(19) United States
(12) Patent Application Publication
(10) Pub. No.: US 2005/0139997 A1
(43) Pub. Date: Jun. 30, 2005

(54) Chip assembly package

(75) Inventor: Che-Ya Chou, Kaohsiung City (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaoshiung (TW)

(21) Appl. No.: 10/876,453

(22) Filed: Jun. 28, 2004

(30) Foreign Application Priority Data
Dec. 31, 2003 (TW) 092137717

(51) Int. Cl. H01L 21/44; H01L 21/48; H01L 21/50; H01L 23/02; H01L 23/34

(52) U.S. Cl. 257/712; 438/122

(57) ABSTRACT

A chip assembly package mainly comprises a substrate, a chip, a plurality of electrically conductive wires, a flat heat spreader. The substrate comprises an upper surface having a chip disposal area and a bonding area surrounding the chip disposal area wherein the flat heat spreader is mounted on the upper surface and at least exposes the bonding area. The chip is disposed above the chip disposal area and mounted on the flat heat spreader. Moreover, the chip is electrically connected to the bonding area by the electrically conductive wires. Besides, an encapsulation is provided to encapsulate the chip, the flat heat spreader and the electrically conductive wires.

### BACKGROUND OF THE INVENTION

1. Field of Invention

This invention relates to a chip assembly package. More particularly, the present invention is related to a chip assembly package characterized in that the heat generated from the chip can be transmitted to the substrate via a heat spreader interposed between the chip and the substrate.

2. Related Art

In semiconductor industries, the manufacture of integrated circuits (ICs) mainly comprises three stages. One is IC design, another is IC manufacture and the other is IC assembly. According to this, IC devices are formed by the steps of forming chips from designing integrated circuits, designing the mask, manufacturing wafers, sawing the wafers into chips and packaging the chips by disposing the chips on the carriers, wire bonding the chips to the carriers and encapsulating the chips and the carriers. Therein, the carrier may be a lead frame or a substrate, and the chips can be electrically connected to external electronic devices through the redistributed traces on the chip, the carriers and the wires or bumps. To be noted, the encapsulation can prevent the moisture affecting the chip.

Generally speaking, a conventional package shall be a wire-bonded package. As shown in FIG. 1, it illustrates a wire-bonded package comprising a substrate 110, a chip 120, a plurality of electrically conductive wires 130 and an encapsulation 140. Therein, the substrate 110 has an upper surface 112 and a lower surface 114 opposed to the upper surface 112, and the upper surface 112 and the lower surface 114 have a plurality of contacts 116a and ball pads 116b formed thereon respectively. Besides, the chip 120 is disposed on the upper surface 112 and electrically connected to the substrate 11o through the wires 130 connecting the contacts 116a and bonding pads 124 formed on the active surface 122 of the chip 120. In addition, the encapsulation 130 encapsulates the chip 120, the wires 130 and a portion of the upper surface 112 of the substrate 110. Moreover, the ball pads 116b formed on the lower surface 114 of the substrate 110 are able to be attached to external devices through a plurality of solder balls 118.

To be noted, there is usually a lot of heat generated from the chip 120 and when the heat is not able to be transmitted to the outside and accumulated in the package, the chip in the package will be damaged and not run well. Consequently, it is an important task to enhance the thermal performance of the package. Besides, in MCM (multi-chips module) package and SIP (system-in-a-package), when the two chips are arranged close to each other, namely separated from each other with a small distance, it is easy to be electrically interfered with each other to cause the chips not well worked. Accordingly, it is another important task to lower the electrical interference between the chips.

Therefore, providing another assembly package to solve the mentioned-above disadvantages is the most important task in this invention.

### SUMMARY OF THE INVENTION

In view of the above-mentioned problems, this invention is to provide a chip assembly package to enhance the thermal performance thereof.

To achieve the above-mentioned, a chip assembly package is provided, wherein said package mainly comprises a substrate, a chip, a plurality of electrically conductive wires, a flat heat spreader, and an encapsulation. The substrate has an upper surface and a lower surface wherein the upper surface has a chip disposal area and a wire-bonding area; the flat heat spreader is disposed above the substrate to expose the wire bonding area; and the wires connect the chip and the wire-bonding area. Besides, the encapsulation covers the chip, the wires and the flat heat spreader. In addition, the substrate further has a grounding pad electrically connecting the flat heat spreader. Moreover, a cap heat spreader is provided to cover the chip to shield the chip against outside electrical interference.

As mentioned above, the flat heat spreader is interposed between the chip and the substrate so as to transmit the heat generated from the chip to the substrate more quickly. Accordingly, the thermal performance of the chip assembly package will be enhanced. Moreover, the flat heat spreader is electrically grounded to the substrate through the grounding pad so as to shield the chip against outside electrical interference.

### BRIEF DESCRIPTION OF THE DRAWINGS

The invention will become more fully understood from the detailed description given herein below illustrations only, and thus are not limitative of the present invention, and wherein:

FIG. 1 is a cross-sectional view of the conventional chip assembly package;

FIG. 2A is a top view of the chip assembly package according to the first embodiment of this invention;

FIG. 2B is a cross-sectional view along I-I′ of the chip assembly package as shown in FIG. 2A;

FIG. 3 is a cross-sectional view of the chip assembly package according to the second embodiment of this invention; and

FIG. 4 is a cross-sectional view of the chip assembly package according to the third embodiment of this invention.

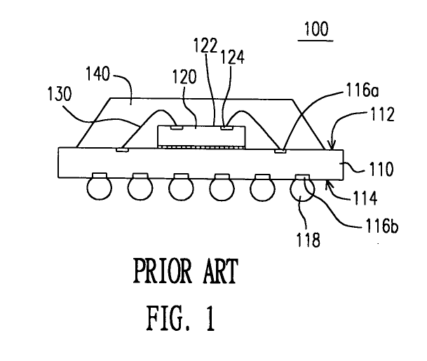

### DETAILED DESCRIPTION OF THE INVENTION

The chip assembly package according to the preferred embodiments of this invention will be described herein below with reference to the accompanying drawings, wherein the same reference numbers refer to the same elements.

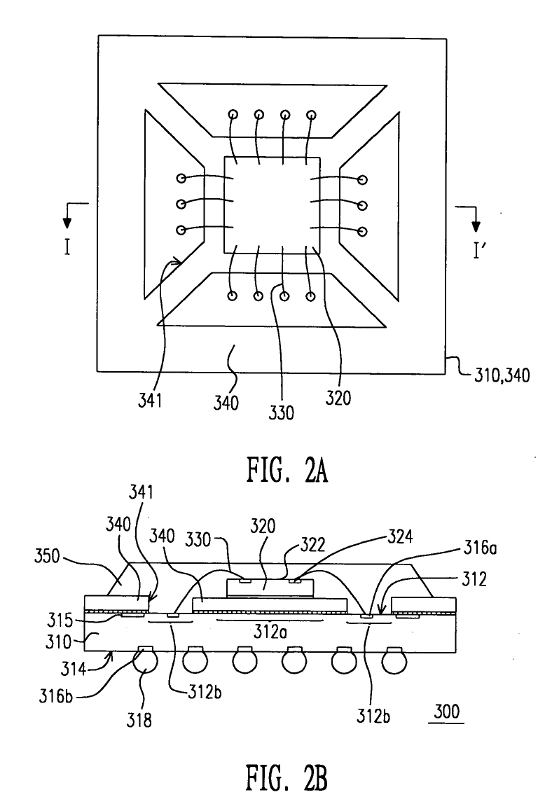

In accordance with a first preferred embodiment as shown in FIGS. 2A and 2B, there is provided a chip assembly package. Said chip assembly package 300 mainly comprises a substrate 310, a chip 320, a plurality of electrically conductive wires 330, a heat spreader 340 and an encapsulation 350. Therein, the substrate 310 has an upper surface 312 having a chip disposal area 312a and a wire-bonding area 312b wherein the chip disposal area 312a is at an central region of the substrate 310 and encompassed by the wire-bonding area 312b and the wire-bonding area has a plurality of contacts 316a formed thereon. The heat spreader 340 at least has an opening 341 and is disposed above the upper surface 312 of the substrate 310 to expose the contacts 316a or the bonding area 312b through the opening 341. Besides, the chip 320 is mounted on the heat spreader 340 and located above the chip disposal area 312a; and is electrically connected to the substrate 310 through the wires 330 connecting the substrate 310 and the bonding pads 324 of the chip 320. Moreover, the encapsulation 350 covers the chip 320, the electrically conductive wires 330 and a portion of the heat spreader 340. Furthermore, the lower surface 314 of the substrate 310 has a plurality of ball pads 316 for attaching solder balls 318 to electrically connect to external devices. Specifically, the heat spreader 340 may be a flat heat spreader.

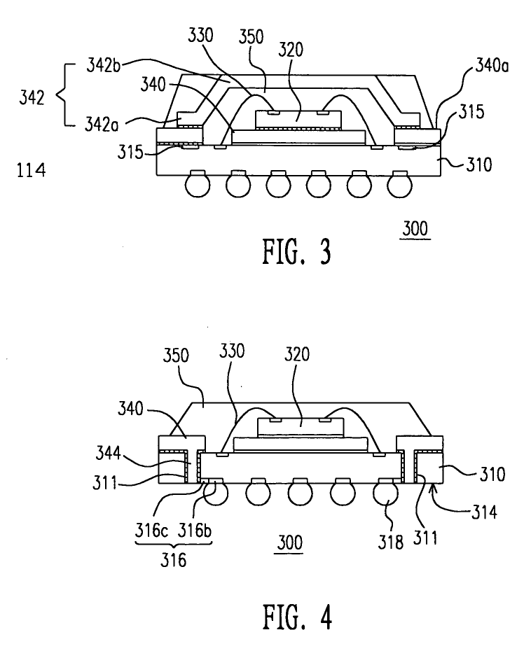

Referring to FIG. 3, it illustrates a second embodiment of this invention. As shown in FIG. 3, the chip assembly package 300 may further comprise a cap heat spreader 342 having a cover 342a and a supporter 342b, wherein the supporter is attached to the heat spreader 340. Because the heat spreader 340 and the cap heat spreader 342 are made of metal with high thermal conductivity, such as aluminum, copper and alloy of copper, and have a better thermal performance than the encapsulation 350, the heat generated from the chip 310 can be quickly transmitted to the surface of the chip assembly package 300 through the heat spreader 340 and the cap heat spreader 342. To be noted, the cap heat spreader 342 can be entirely encapsulated in the encapsulation 350 or partially encapsulated in the encapsulation 350 so as to expose the surface of the cap 342 of the cap heat spreader 340. Besides, the upper surface 340a of the heat spreader 340 can be exposed out of the encapsulation 350 to enhance the thermal performance. As mentioned above and referring to FIG. 2B and FIG. 3, there is provided a grounding pad 315 formed on the upper surface 312 of the substrate 310, and the heat spreader 340 and the cap heat spreader 342 are able to be electrically grounded to the substrate 310 via the grounding pad 315 to shield the chip 320 against outside electrical interference.

Besides, referring to FIG. 4, it illustrates a third embodiment of this invention. As shown in FIG. 4, what is the difference of the third embodiment from the second embodiment is that the bottom of the flat heat spreader 340 further has a thermally conductive plug 344 and the substrate 310 has a corresponding through hole 311 for disposing the thermally conductive plug 344 therein. Moreover, the lower surface 314 of the substrate 310 has a patterned trace 316 to form a thermal ball pad 316b and a bottom trace 316c. To be noted, the thermally conductive plug 344 is able to connect the bottom trace 316c so that the heat generated from the chip 320 can be conveyed to the thermal ball 318 attached on the thermal ball pad 316b through the thermally conductive plug 344 and the bottom trace 316c. Thus, the thermal performance of the chip assembly package will be enhanced to prevent all the heat from being kept and accumulated in the chip 320.

Although the invention has been described in considerable detail with reference to certain preferred embodiments, it will be appreciated and understood that various changes and modifications may be made without departing from the spirit and scope of the invention as defined in the appended claims.

1. A chip assembly package, comprising:
a substrate having an upper surface having a chip disposal area, a bonding area and a lower surface;
a heat spreader, the heat spreader having an opening and disposed above the upper surface of the substrate, wherein the opening exposes the bonding area;
a chip, the chip disposed over the chip disposal area of the upper surface of the substrate and located above the heat spreader;
a plurality of electrically conductive wires electrically connecting the chip and the bonding area of the substrate; and
an encapsulation covering the chip, the electrically conductive wires and the heat spreader.

2. The chip assembly package of claim 1, wherein the heat spreader is a flat heat spreader.

3. The chip assembly package of claim 1, wherein the heat spreader is made of electrically conductive material and the substrate further has a grounding pad electrically connected to the heat spreader.

4. The chip assembly package of claim 1, further comprising a plurality of solder balls formed on the lower surface.

5. The chip assembly package of claim 1, wherein the heat spreader further has a thermally conductive plug penetrating the upper surface of the substrate and disposed in the surface.

6. The chip assembly package of claim 5, wherein the lower surface of the substrate further has a patterned trace comprising a bottom trace connecting to the thermally conductive plug and a thermal ball pad attached to a thermal ball.

7. The chip assembly package of claim 1, further comprising a cap heat spreader covering the chip and the electrically conductive wires wherein the cap heat spreader attaches to the heat spreader.

8. The chip assembly package of claim 7, wherein the encapsulation covers the cap heat spreader.

9. The chip assembly package of claim 7, wherein the encapsulation exposes the cap heat spreader.

10. A chip assembly package, comprising:
a substrate having an upper surface having a chip disposal area and a plurality of contacts;
a heat spreader, the heat spreader having an opening and disposed above the upper surface of the substrate, wherein the opening exposes the contacts;
a chip, the chip disposed over the chip disposal area of the upper surface of the substrate and located above the heat spreader; and
a plurality of electrically conductive wires electrically connecting the chip and the contacts.

11. The chip assembly package of claim 10, wherein the heat spreader is a flat heat spreader.

12. The chip assembly package of claim 10, wherein the substrate further has a grounding pad electrically connected to the heat spreader.

13. The chip assembly package of claim 10, wherein the substrate further has a through hole penetrating the upper surface.

14. The chip assembly package of claim 13, wherein the heat spreader further has a thermally conductive plug disposed in the through hole of the substrate.

15. The chip assembly package of claim 14, wherein the substrate further has a lower surface and a thermal ball pad formed on the lower surface, and the thermally conductive plug thermally connects the thermal ball pad.

16. The chip assembly package of claim 10, further comprising a cap heat spreader covering the chip and the electrically conductive wires wherein the cap heat spreader has a supporter attaching to the heat spreader.

17. The chip assembly package of claim 16, further comprising an encapsulation covering the chip, the electrically conductive wires, the heat spreader.

18. The chip assembly package of claim 17, wherein the encapsulation further covers the cap heat spreader.

19. The chip assembly package of claim 18, wherein the encapsulation exposes the cap heat spreader.

20. The chip assembly package of claim 17, wherein the heat spreader is exposed out of the encapsulation.

21. The chip assembly package of claim 15, further comprising a thermal ball attached to the thermal ball pad.
